(19) United States
(12) Patent Application Publication
(10) Pub. No.: US 2025/0167020 A1
(43) Pub. Date: May 22, 2025

(54) SUBSTRATE PROCESSING STATUS MONITORING DEVICE AND SUBSTRATE PROCESSING STATUS MONITORING METHOD

(71) Applicant: KURASHIKI BOSEKI KABUSHIKI KAISHA, Okayama (JP)

(72) Inventors: Noboru HIGASHI, Osaka (JP); Naoki OHNE, Osaka (JP); Kota SOTOKU, Osaka (JP)

(73) Assignee: KURASHIKI BOSEKI KABUSHIKI KAISHA, Okayama (JP)

(21) Appl. No.: 18/840,892

(22) PCT Filed: Mar. 16, 2023
(86) PCT No.: PCT/JP2023/010310

§ 371 Date: Aug. 22, 2024

(30) Foreign Application Priority Data
Mar. 30, 2022 (JP) 2022-055201

(51) Int. Cl. H01L 21/67

(52) U.S. Cl. CPC H01L 21/67253; H01L 21/67023

(57) ABSTRACT

A substrate processing status monitoring device (20) for monitoring a status of substrate processing performed by supplying a processing solution (S) onto a substrate (W) that is rotating, the substrate processing status monitoring device (20) including a light projecting unit (22) that irradiates the substrate with light, a light receiving unit (22) that receives light that has passed through the processing solution, a photometry unit (23) that simultaneously disperses light received by the light receiving unit into a plurality of wavelengths and simultaneously measures light intensities of the plurality of wavelengths, and an operation unit (24) that detects a change in the status of the substrate processing by generating an optical spectrum from the light intensities of the plurality of wavelengths measured by the photometry unit and comparing the optical spectrum with a reference spectrum or the optical spectrum of past previously generated during the substrate processing.

### TECHNICAL FIELD

The present invention relates to a device that monitors a status of substrate processing in single wafer processing performed by supplying a processing solution onto a substrate such as a semiconductor wafer.

### BACKGROUND ART

In single wafer processing in the semiconductor industry, a process such as etching or cleaning is performed by supplying a processing solution to a surface of a semiconductor wafer while holding and rotating the semiconductor wafer horizontally or the like.

Patent Literature 1 describes a method for measuring the abundance of one or more components contained in a processing solution film from the absorbance at a predetermined wavelength, the method including irradiating a liquid film of a processing solution formed on an upper surface of a substrate with infrared rays while supplying the processing solution on the substrate that is rotating, to receive reflected light from the liquid film. This method makes it possible to monitor, for example, the abundance of H₂O remaining in 2-propanol (IPA) after the processing solution is switched from pure water for rinse processing to the IPA for drying processing.

Patent Literature 2 describes an etching processing device that determines a film thickness to be processed based on an optical spectrum of reflected light from a wafer during dry etching processing of a semiconductor wafer using plasma, and compares the film thickness with a threshold value to determine an end point of the etching processing.

### CITATION LIST

### Patent Literature

Patent Literature 1: JP 2016-070669 A
Patent Literature 2: WO 2020/161887 A
Patent Literature 3: JP H3-209149 A

### SUMMARY OF INVENTION

### Technical Problem

However, the method described in Patent Literature 1 monitors the state of a specific element, that is, a component of the processing solution, and does not monitor the progress status of the entire substrate processing including the state other than the component of the processing solution, for example, the state of the surface of the substrate. The etching processing described in Patent Literature 2 is not a wet process of supplying a processing solution to process a substrate.

In monitoring the status of the single wafer processing, many advantages can be obtained if various pieces of information changing during the processing can be monitored as a whole, instead of only measuring specific components in the processing solution or measuring the film thickness of the thin film on the substrate surface. For example, it is possible to determine whether it is necessary to perform an additional inspection by detecting whether the processing has progressed normally. In addition, for example, the processing condition can be feedback-controlled by detecting that the status of the processing has deviated from the status normally observed at the time of the processing. However, in the single wafer processing performed by supplying a processing solution onto a substrate, there has been no device that monitors the status of the substrate processing as a whole. Here, monitoring as a whole means that the state of the substrate processing is comprehensively monitored instead of measuring and monitoring specific elements in the substrate processing such as the concentration of the processing solution and the thickness of the processing solution film.

The present invention has been made in view of the above, and an object of the present invention is to provide a device for monitoring a status of substrate processing in single wafer processing performed by supplying a processing solution onto a substrate.

### Solution to Problem

A substrate processing status monitoring device of present invention is a substrate processing status monitoring device for monitoring a status of substrate processing performed by supplying a processing solution onto a substrate that is rotating, the substrate processing status monitoring device including a light projecting unit that irradiates the substrate with light in a state where the processing solution is on the substrate, a light receiving unit that receives light that has passed through the processing solution, a photometry unit that simultaneously disperses light received by the light receiving unit into a plurality of wavelengths and simultaneously measures light intensities of the plurality of wavelengths, and an operation unit that detects a change in the status of the substrate processing by generating an optical spectrum from the light intensities of the plurality of wavelengths measured by the photometry unit and comparing the optical spectrum with a reference spectrum or the optical spectrum of past previously generated during the substrate processing.

Here, simultaneously dispersing into a plurality of wavelengths means that the dispersed light of each wavelength is part of the light received at the same time without being temporally shifted. Simultaneously measuring light intensities of a plurality of wavelengths means that the light intensities of the respective wavelengths are light intensities at the same time without being temporally shifted. The reference spectrum refers to an optical spectrum when the same substrate processing as the substrate processing to be monitored is correctly performed or when an abnormality has occurred.

According to this configuration, it is possible to grasp the status of the entire substrate processing including the state of the processing solution, the surface of the substrate, and the like by acquiring the optical spectrum of the light that has passed through the processing solution. Further, the progress status of the substrate processing can be monitored by obtaining the deviation of the optical spectrum generated during the processing from the reference spectrum and the amount of change from the optical spectrum previously generated during the substrate processing being executed.

Preferably, the operation unit detects the change in the status of the substrate processing by comparing the optical spectrum with the reference spectrum and updates the reference spectrum using the optical spectrum. Updating the reference spectrum using the optical spectrum includes simply replacing the reference spectrum with a newly obtained optical spectrum, and replacing the reference spectrum with an operation result using the newly obtained optical spectrum and the previous reference spectrum, for example, a simple average or a weighted average of the newly obtained optical spectrum and the previous reference spectrum.

Alternatively, preferably, the operation unit detects the change in the status of the substrate processing by calculating a corrected optical spectrum obtained by excluding an influence of noise from the optical spectrum instead of the optical spectrum from the light intensities of the plurality of wavelengths measured by the photometry unit and comparing the corrected optical spectrum with a corrected reference spectrum obtained by excluding the influence of noise from the reference spectrum or the corrected optical spectrum of past previously calculated during the substrate processing. Here, the noise refers to various factors that fluctuate the light intensity to be measured regardless of the change in the status of the substrate processing that is originally desired to be detected. Since the optical spectrum obtained from the measurement light simultaneously includes a lot of information such as a change in light intensity due to the processing solution and a change in light intensity due to the status of the substrate surface, a change in the status of the substrate surface in the status of the substrate processing can be detected more clearly by using the corrected optical spectrum in which a change component of the light intensity due to the processing solution is excluded from the optical spectrum, for example.

The operation unit can calculate the corrected optical spectrum and the corrected reference spectrum by excluding the influence of the noise from the optical spectrum and the reference spectrum, respectively, through static data processing. Alternatively, the operation unit can calculate the corrected optical spectrum and the corrected reference spectrum by excluding the influence of noise from the optical spectrum and the reference spectrum, respectively, through dynamic data processing. Preferably, the noise excluded by the dynamic data processing is noise caused by an undulation of the processing solution. Here, the static data processing refers to processing of removing noise through a predetermined operation without analyzing the measured optical spectrum, and the dynamic data processing refers to processing of removing noise based on a result of analyzing the measured optical spectrum.

When the change in the status of the substrate processing is detected by using the corrected optical spectrum, the operation unit preferably detects the change in the status of the substrate processing by comparing the corrected optical spectrum with the corrected reference spectrum and updates the corrected reference spectrum using the corrected optical spectrum.

Preferably, the substrate processing status monitoring device further includes a control unit that changes a condition of the substrate processing based on the change in the status of the substrate processing that has been detected.

Preferably, the photometry unit measures the light intensities of the plurality of wavelengths using a time that is a natural number multiple of a rotation period of the substrate as an exposure time. By synchronizing the exposure time with the rotation period of the substrate, it is possible to equalize the fluctuation of the optical spectrum due to the position of the substrate surface in the circumferential direction.

Alternatively, preferably, the photometry unit measures the light intensities of the plurality of wavelengths in an exposure time of 2.5 milliseconds or less. Shortening the exposure time makes it possible to enhance the spatial resolution of the region to be measured. In addition, the influence of noise on the optical spectrum, in particular, the influence of noise such as an undulation of the processing solution requiring dynamic data processing can be easily checked.

Preferably, the photometry unit disperses the light received by the light receiving unit into 32 or more of wavelengths.

Preferably, the photometry unit includes a linear variable filter and disperses the light received by the light receiving unit with the linear variable filter.

A substrate processing status monitoring device of the present invention is a substrate processing status monitoring device for monitoring a status of substrate processing performed by supplying a processing solution onto a substrate that is rotating, the substrate processing status monitoring device including a light projecting unit that irradiates the substrate with light in a state where the processing solution is on the substrate, a light receiving unit that receives light that has passed through the processing solution, a photometry unit that simultaneously disperses light received by the light receiving unit into a plurality of wavelengths and simultaneously measures light intensities of the plurality of wavelengths, and an operation unit that estimates an abnormality of the substrate processing by calculating an optical spectrum or a corrected optical spectrum obtained by excluding an influence of noise from the light intensities of the plurality of wavelengths measured by the photometry unit and inputting the optical spectrum or the corrected optical spectrum to a substrate processing status estimation model learned through machine learning for estimating an abnormality of the status of the substrate processing.

A substrate processing status monitoring method of the present invention is a substrate processing status monitoring method for monitoring a status of substrate processing performed by supplying a processing solution onto a substrate that is rotating, the substrate processing status monitoring method including a light projecting step of irradiating the substrate with light in a state where the processing solution is on the substrate, a light receiving step of receiving light that has passed through the processing solution and is reflected from a surface of the substrate, a photometry step of simultaneously dispersing light received in the light receiving step into a plurality of wavelengths and simultaneously measuring light intensities of the plurality of wavelengths, an optical spectrum generation step of generating an optical spectrum from the light intensities of the plurality of wavelengths measured in the photometry step, and a detection step of detecting a change in the status of the substrate processing by comparing the optical spectrum with a reference spectrum or the optical spectrum of past previously generated during the substrate processing.

Preferably, the substrate processing status monitoring method includes, instead of the optical spectrum generation step, a corrected optical spectrum calculation step of calculating a corrected optical spectrum obtained by excluding an influence of noise from the light intensities of the plurality of wavelengths measured in the photometry step, wherein the detection step is a step of detecting the change in the status of the substrate processing by comparing the corrected optical spectrum with a corrected reference spectrum from which the influence of noise is excluded or the corrected optical spectrum of past previously calculated during the substrate processing.

### Advantageous Effects of Invention

According to the substrate processing status monitoring device of the present invention, it is possible to grasp the situation of the entire substrate processing including the state of the processing solution, the surface of the substrate, and the like by acquiring the optical spectrum of the light that has passed through the processing solution. Further, the progress status of the substrate processing can be monitored by obtaining the deviation of the optical spectrum generated during the processing from the reference spectrum and the amount of change from the optical spectrum previously generated during the substrate processing being executed.

### BRIEF DESCRIPTION OF DRAWINGS

FIG. 1 is a diagram illustrating a configuration of a substrate processing device and a substrate processing status monitoring device according to first to third embodiments.

FIG. 2 is a diagram illustrating a structure of a probe that serves as both a light projecting unit and a light receiving unit.

FIG. 3 is a diagram illustrating a structure of a photometry unit.

FIG. 4 includes a diagram illustrating another structure of the photometry unit. FIG. 4A is an AA sectional view of FIG. 4B, and FIG. 4B is a BB sectional view of FIG. 4A.

FIG. 5 is a process flowchart of a method for using the substrate processing status monitoring device according to the first embodiment.

FIG. 6 is a process flowchart of another method for using the substrate processing status monitoring device according to the first embodiment.

FIG. 7 is a process flowchart of a method for using the substrate processing status monitoring device according to a second embodiment.

FIG. 8 is a process flowchart of another method for using the substrate processing status monitoring device according to the second embodiment.

FIG. 9 is an example of a measurement result illustrating a difference in optical spectrum due to a difference in a pattern on a surface of a silicon wafer.

FIG. 10 is a diagram for describing the influence of undulation of a processing solution on light intensity.

FIG. 11 is a diagram for describing the influence of undulation of the processing solution on light intensity.

FIG. 12 is a diagram for describing the influence of undulation of the processing solution on light intensity.

FIG. 13 is an example of a measurement result of an IPA concentration in a processing solution.

### DESCRIPTION OF EMBODIMENTS

A first embodiment of a substrate processing status monitoring device of the present invention will be described by taking processing of a semiconductor wafer as an example. The substrate processing status monitoring device according to the present embodiment irradiates a wafer being processed with light, and monitors the status of substrate processing using the optical spectrum of reflected light from the wafer.

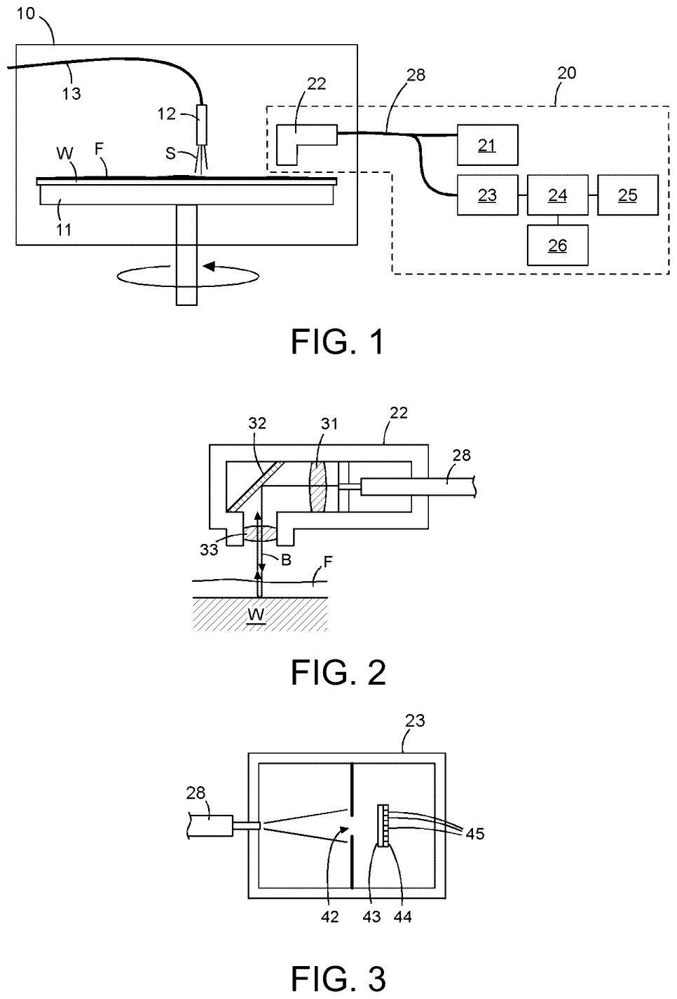

Referring to FIG. 1, a single wafer type substrate processing device 10 includes a rotary table 11 that rotates a wafer W while holding the wafer W horizontally or at a desired angle, and a nozzle 12 that supplies a processing solution S onto the wafer. A plurality of nozzles 12 are respectively provided for different types of processing solutions, and each nozzle is connected to a processing solution supply source (not illustrated) by a pipe 13. The nozzle 12 is movable in a radial direction from the center to the outer edge of the wafer. When the processing solution S is supplied to the upper surface of the wafer W while the wafer W is rotated, the processing solution moves toward the outer edge of the wafer because of centrifugal force, and a processing solution film F having a film thickness in which the movement amount and the supply amount are balanced is formed. When the supply of the processing solution is stopped, the processing solution is discharged from the outer edge of the wafer, and the processing solution film decreases in film thickness and eventually disappears.

The type of the processing solution S is not particularly limited. Examples of the processing solution include an ammonia hydrogen peroxide water mixed solution, a sulfuric acid hydrogen peroxide water mixed solution, a hydrochloric acid hydrogen peroxide water mixed solution, dilute hydrofluoric acid, and ozone water used for various types of cleaning processing, hydrofluoric acid, nitric acid, acetic acid, phosphoric acid, and mixed acids obtained by mixing them used for various types of etching processing, pure water used for rinse processing, and IPA used for drying processing.

The content of the substrate processing is not particularly limited, and it is possible to monitor the status of the cleaning processing, the etching processing, the drying processing, and the like. The status of the substrate processing includes the concentration of the processing solution and the thickness of the liquid film in various types of processing, the thickness of the oxide film and the nitride film on the substrate surface in the etching processing, and the state of the wafer surface during various types of processing, for example, the presence or absence of pattern collapse.

The substrate processing status monitoring device 20 includes a light source 21, a probe 22, a photometry unit 23, an operation unit 24, a recording unit 25, and a control unit 26. The probe 22 is disposed above the wafer W inside the substrate processing device 10, and in the present embodiment, serves both as a light projecting unit that irradiates the wafer W with light and as a light receiving unit that receives reflected light that returns from the substrate through the processing solution on the wafer. The light source 21, the photometry unit 23, the operation unit 24, the recording unit 25, and the control unit 26 are disposed outside the substrate processing device 10. The light source 21 and the probe 22, and the probe 22 and the photometry unit 23 are connected by an optical fiber 28. The optical fiber extending from the probe 22 branches halfway, and one of the branches reaches the light source 21 and the other reaches the photometry unit 23. The operation unit 24 is electrically connected to the photometry unit 23, the recording unit 25, and the control unit 26.

The light source 21 generates light including at least a plurality of wavelengths, and preferably generates light in a continuous wavelength range. The wavelength of the light generated by the light source can be determined according to the purpose. For example, it is possible to measure the amount of absorption by the components in the processing solution by causing the light source to generate light containing infrared rays. In addition, for example, it is possible to monitor the status of a wafer surface by causing the light source to generate light including a wavelength range in which interference due to a thin film or a pattern formed on the wafer surface can be observed. As the light source 21, a known lamp, for example, a commercially available lamp such as a halogen tungsten lamp can be used.

Referring to FIG. 2, the probe 22 emits a light beam B from above the wafer W toward the wafer W, and receives light reflected from the surface of the wafer through the processing solution film F. That is, in the present embodiment, the probe 22 serves both as a light projecting unit that emits light toward the processing solution on the wafer W and as a light receiving unit that receives light reflected from the surface of the wafer. The light introduced from one end (right end in FIG. 2) of the probe from the light source 21 through the optical fiber 28 travels horizontally toward the left side in FIG. 2, is collimated by a lens 31, is reflected downward by a mirror 32, passes through a lens 33, and is emitted vertically toward the wafer W. The light beam having passed through the processing solution film F on the wafer and reflected by the wafer W passes through the lens 33, and is guided to the optical fiber 28 in the reverse direction in the probe. The probe 22 is movable in the radial direction from the center to the outer edge of the wafer.

Referring to FIG. 3, the photometry unit 23 includes a slit 42, a linear variable filter (hereinafter referred to as “LVF”) 43, and a photodiode (PD) array 44. The light introduced from one end (the left end in FIG. 3) of the photometry unit through the optical fiber 28 from the probe 22 travels toward the right side in FIG. 3, is narrowed to the width of the LVF by the vertically long slit 42, and is dispersed by the LVF 43, and light intensities of a plurality of wavelengths are measured by the PD array 44.

The LVF 43 is a spectral filter having a different transmission wavelength according to an incident position along one direction of the substrate. As the LVF, various known LVFs can be used. Using the LVF makes it possible to simultaneously disperse the received light into a plurality of wavelengths. Simultaneously dispersing means that the dispersed light of each wavelength is part of the light received at the same time without being temporally shifted. For example, when light is dispersed while a plurality of interference filters that transmit light of different wavelengths are exchanged, it does not mean that the light is simultaneously dispersed. Means for simultaneously dispersing light is not limited to the LVF, and for example, light from an optical fiber is applied to a diffraction grating, whereby simultaneously dispersed light is obtained as reflected light from the diffraction grating.

In the PD array 44, PD elements 45 are linearly arranged in parallel, and the intensity of light transmitted through different positions of the LVF 43 is measured by each PD element, whereby light intensities of a plurality of dispersed wavelengths are simultaneously measured. Simultaneously measuring light intensities of a plurality of wavelengths means that each PD element of the PD array measures the intensities of a plurality of pieces of light at the same time, and more precisely means that each PD element starts exposure at the same time, ends the exposure at the same time, to measure the light intensity.

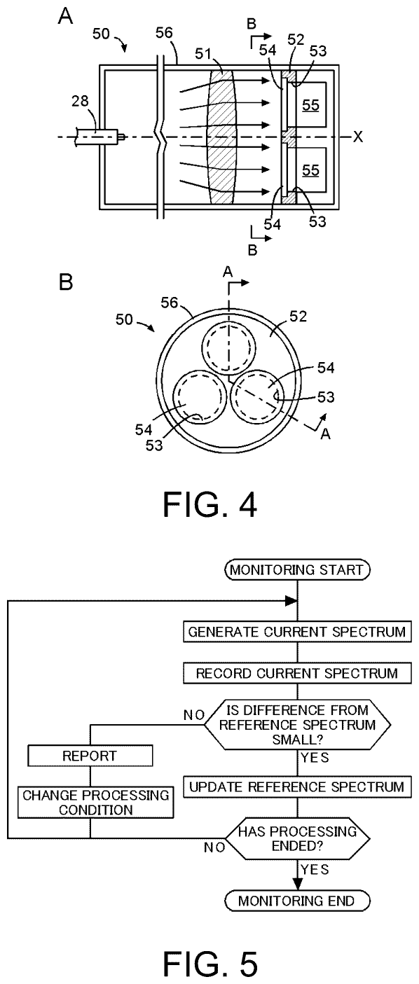

As another means for simultaneously dispersing light into a plurality of wavelengths and simultaneously measuring the light intensity of each wavelength, in the experiment described later, a spectrophotometer in which an interference filter that transmits light of different wavelengths and a PD element are disposed at rotationally symmetric positions around an optical axis was used (FIG. 4).

In a spectrophotometer 50 illustrated in FIG. 4, light introduced from the optical fiber 28 connected to one end (the left end in FIG. 4) of a substantially cylindrical housing 56 is collimated into a bundle of light beams parallel to an optical axis X of the optical fiber by the lens 51. In the optical path, a partition wall 52 that does not pass light is provided perpendicular to the optical axis X, and openings 53 having the same shape and the same area are formed in the partition wall 52 so as to be rotationally symmetric about the optical axis X. Since the openings are disposed rotationally symmetrically with respect to the optical axis X, the distances from the optical axis are equal, and the intensities of light entering the respective openings are equal. In each opening 53, a bandpass filter (BPF) 54 that transmits light of different wavelengths is disposed so as to close the entire opening, and a light detection element 55 is disposed behind the BPF (on the opposite side from the optical fiber). As a result, the light introduced from the optical fiber 28 is simultaneously dispersed, and the light intensity of each wavelength is simultaneously measured. The number of openings is not limited to three, but is preferably three or four. In addition, the light intensity can be measured for a larger number of wavelengths by branching the optical fiber from the probe 22 and connecting the branches of the optical fiber to a plurality of spectrophotometers 50 in parallel.

Returning to FIG. 3, the number of PD elements 45 constituting the PD array 44, that is, the number of wavelengths of the optical spectrum is preferably 32 or more, and more preferably 64 or more. As the wavelength resolution of the optical spectrum is higher, the progress status of the wafer processing can be more accurately grasped. On the other hand, the number of PDs included in the PD array is preferably 512 or less, and more preferably 256 or less. This is because there is no particular advantage by having a further increased wavelength resolution of the optical spectrum, and since the amount of light reaching each PD element becomes small, the measurement accuracy of the light intensity decreases, or it becomes necessary to increase the exposure time.

The exposure time of the PD array 44 for generating the optical spectrum during the monitoring of the wafer processing is preferably a natural number multiple of the rotation period of the wafer W. While the PD array is exposed to the reflected light from the wafer, the position on the wafer from which the reflected light is emitted is moved because of the rotation of the wafer. Setting the exposure time to a natural number multiple of the rotation period of the wafer allows the reflected light from all the positions on the circumference where the probe 22 passes above to be uniformly received regardless of the start of the exposure from any moment. This makes it possible to equalize the fluctuation of the reflection spectrum due to the position in the circumferential direction of the wafer surface. To synchronize the exposure time with the rotation period of the wafer, for example, every time the wafer rotates once, a synchronization signal may be transmitted from the substrate processing device 10 to the operation unit 24, and the operation unit 24 may start and end the exposure in accordance with the synchronization signal.

Alternatively, the exposure time of the PD array 44 is preferably 2.5 ms or less, and more preferably 1.5 ms or less. Shortening the exposure time makes it possible to enhance the spatial resolution of the region to be measured. In addition, the influence of the processing solution on the measured light intensity can be easily checked.

When the exposure time of the PD array 44 is shorter than the rotation period of the wafer W, the same position on the wafer can be measured every time the wafer rotates once by setting the sampling period at which the exposure is performed to 1/natural number of the rotation period of the wafer. As a result, for example, when an abnormal optical spectrum is detected, it is easy to specify the position on the wafer.

The operation unit 24 receives light intensities of a plurality of wavelengths from the photometry unit 23 and generates an optical spectrum. The optical spectrum can be represented as a list of light intensities for respective wavelengths and can be treated as vector data. The optical spectrum may be generated from one measurement result of the light intensity received from the photometry unit, or may be generated by integrating a plurality of measurement results of the light intensity. The optical spectrum generated by the operation unit 24 is recorded in the recording unit 25.

The operation unit 24 detects a change in the status of wafer processing by comparing the generated optical spectrum with a reference spectrum or the optical spectrum of past previously generated during wafer processing currently being monitored and recorded in the recording unit 25. The reference spectrum is an optical spectrum when the same processing as the processing to be monitored is correctly performed or when an abnormality has occurred. More precisely, the reference spectrum is an optical spectrum when it is determined that there is no abnormality through the processing when the same substrate processing as the processing to be monitored is performed under the same conditions and the measurement is performed under the same conditions, or when it is determined that an abnormality has occurred during the processing or the processing has reached a situation requiring attention to the abnormality.

When it is desired to monitor the status of the processing solution, the light absorption spectrum includes a lot of information, and when it is desired to monitor the status of the thin film or the pattern on the wafer surface, the optical interference spectrum includes a lot of information. The operation unit 24 can separate the light absorption component and the interference component in the optical spectrum through data processing. Correction of the measured optical spectrum through data processing will be described in a second embodiment.

The optical spectrum generated by the operation unit 24 is recorded in the recording unit 25. The recording unit can be realized by a main storage device, an auxiliary storage device, or a combination thereof. Preferably, the recording unit includes both a main storage device and an auxiliary storage device, and the optical spectrum generated from moment to moment during the processing of monitoring the status is recorded in the main storage device and used for various operations by the operation unit 24, and a reproduction is recorded in the auxiliary storage device.

The recording unit 25 also records a reference spectrum for comparison with the optical spectrum generated during processing. Since the optical spectrum during the substrate processing continuously changes with the progress of the reaction or the like, the recording unit records a series of optical spectra when the processing is correctly performed or an optical spectrum when an abnormality has occurred as a series of reference spectra. Practically, the recording unit 25 records an optical spectrum that can be a reference spectrum for comparison together with processing conditions such as a discharge amount of the processing solution, a wafer rotation speed, and a wafer temperature, and measurement conditions such as a measurement position on the wafer, an exposure time of the photometry unit 23, and an integration time for generating an optical spectrum. At the time of substrate processing monitoring, an optical spectrum recorded under the same processing conditions and measurement conditions from among the recorded optical spectra can be adopted as the reference spectrum. When the optical spectrum at the time of correct processing is used as the reference spectrum and the processing having a large amount of change in the optical spectrum during the processing is performed, the optical spectrum generated during the processing can be compared with, for example, the reference spectrum having the same elapsed time from the start of the processing among the series of reference spectra. The series of reference spectra is preferably recorded in the auxiliary storage device of the recording unit.

When it is determined that a change in the status of wafer processing is an abnormal change as a result of detecting the change with the operation unit 24, the control unit 26 may instruct the substrate processing device 10 to change the processing condition based on the detected change in the status of wafer processing.

Next, for a method for using the substrate processing status monitoring device 20 according to the present embodiment, first, a case where an optical spectrum generated during wafer processing is compared with a reference spectrum will be described along the flow of FIG. 5. Here, a description will be given on the assumption that the reference spectrum is an optical spectrum when the same processing as the processing to be monitored is correctly performed.

In the present specification, the latest optical spectrum generated during the processing currently being monitored is referred to as “current spectrum”, and the optical spectrum that is not the latest but was previously generated during the processing currently being monitored is referred to as “past spectrum”.

Referring to FIG. 5, when the processing is started, the wafer W is rotated, and the processing solution is supplied onto the wafer, then monitoring is started. In a state where the processing solution flows on the surface of the wafer, light is emitted from the probe 22 toward the wafer, light passing through the processing solution and reflected from the surface of the wafer is received by the probe, the photometry unit 23 measures light intensities of a plurality of wavelengths, and the operation unit 24 generates an optical spectrum (current spectrum). The generated current spectrum is recorded in the recording unit 25.

Next, the operation unit 24 compares the current spectrum with the reference spectrum. The reference spectrum to be compared is, for example, a reference spectrum having the same elapsed time from the start of processing among the series of reference spectra recorded in the recording unit 25. As a method for comparing the current spectrum with the reference spectrum, for example, the squares of the differences in all wavelengths may be integrated by the following formula, and whether the progress status of the processing is abnormal or normal may be determined based on whether this value exceeds a preset threshold value.

$$\sum {( Ii - Iri )}^{2}$$

Ii and Iri are the intensities of the current and reference spectra at wavelength λi

In addition, there is a case where an abnormality can be detected more efficiently and with higher accuracy by focusing on the shape of the spectrum rather than the absolute value of the light intensity. From this point, the difference between the light intensities of the two different wavelengths λ1 and λ2 may be obtained by the following formula, and whether the progress status of the processing is abnormal or normal may be determined based on whether this value exceeds a preset threshold value.

$$( I 1 - I 2 ) - ( Ir 1 - Ir 2 )$$

The suffixes 1, 2 denote wavelengths λ1 and λ2, respectively, and r denotes reference spectrum.

When it is determined that the difference between the current spectrum and the reference spectrum is large and the progress status of processing is abnormal as a result of comparison between the current spectrum and the reference spectrum with the operation unit 24, the abnormality is reported to the administrator, and the control unit 26 may further instruct the substrate processing device 10 to change the processing condition.

When it is determined that the difference between the current spectrum and the reference spectrum is small and the progress status of processing is normal as a result of comparison between the current spectrum and the reference spectrum with the operation unit 24, the operation unit 24 may update the reference spectrum. For example, the reference spectrum can be replaced with the current spectrum or a moving average of a predetermined number of optical spectra obtained before the current spectrum. Alternatively, the reference spectrum may be replaced with a simple average, a weighted average, or the like of the reference spectrum and the current spectrum.

The above procedure is repeated until the wafer processing is completed.

Since the comparison between the current spectrum and the reference spectrum is repeatedly performed, a change in the comparison result, for example, whether a difference between the two is widened, or the like may be considered in determining whether the progress status of processing is normal.

When an optical spectrum at the time of occurrence of an abnormality is used as a reference spectrum, whether a value of each of the above formulas exceeds a preset threshold value is used as a criterion of whether a difference between the current spectrum and the reference spectrum is large or small. When the difference between the current spectrum and the reference spectrum is small, it can be determined that an abnormality has occurred in processing.

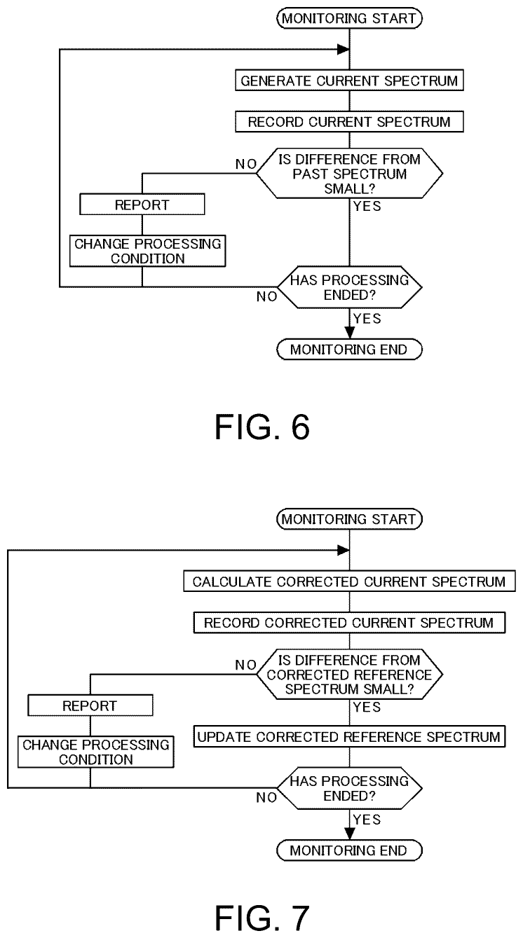

Next, as another method for using the substrate processing status monitoring device 20 according to the present embodiment, a case where the current spectrum is compared with the past spectrum will be described with reference to FIG. 6. Hereinafter, steps different from those in FIG. 5 will be described.

The optical spectrum generated during the wafer processing changes with the progress of the reaction or the like, but the change is continuous. Thus, when there is an abrupt change between the current spectrum and the past spectrum, particularly between the current spectrum and the past spectrum obtained by sampling one time before the current spectrum, it is considered that there is a high possibility that some unexpected abnormality has occurred.

In the method of comparing the current spectrum with the past spectrum, for example, the squares of the differences in all wavelengths may be integrated by the following formula, and whether the progress status of processing is abnormal or normal may be determined based on whether this value has abruptly changed.

$$\sum {( Ii - Ipi )}^{2}$$

Ipi is the intensity of the past spectrum at the wavelength λi

In addition, the difference between the light intensities of the two different wavelengths λ1 and λ2 may be obtained by the following formula, and it may be determined whether the progress status of processing is abnormal or normal based on whether this value has abruptly changed.

$$( I 1 - I 2 ) - ( Ip 1 - Ip 2 )$$

Whether the change is abrupt can be determined by whether the amount of change is equal to or greater than a preset threshold value or whether the change rate exceeds a preset threshold value range.

When the substrate processing status monitoring device 20 according to the present embodiment is used, both the comparison between the current spectrum and the reference spectrum (FIG. 5) and the comparison between the current spectrum and the past spectrum (FIG. 6) may be performed.

In the present embodiment, the current spectrum reflects the status of the wafer surface at that time, the status of the wafer surface including a thin film such as an oxide film when the thin film is formed on the wafer surface, and the status of the processing solution on the wafer. By monitoring the current spectrum in which a piece of information from the substrate and a piece of information from the processing solution are mixed and comparing the current spectrum with the reference spectrum or the past spectrum like this, it is possible to check whether the process is normally progressing.

Next, a second embodiment of the substrate processing status monitoring device of the present invention will be described by taking processing of a semiconductor wafer as an example like the first embodiment. The substrate processing status monitoring device according to the present embodiment monitors the status of the substrate surface using a spectrum obtained by excluding the influence of noise from the optical spectrum of reflected light from the wafer.

In the present specification, “noise” refers to various factors that fluctuate the light intensity to be measured regardless of the change in the status of the substrate processing that is originally desired to be detected. For example, in processing performed by supplying a processing solution onto a wafer, the processing solution may undulate depending on a type of the processing solution and processing conditions. When the processing solution undulates, the optical spectrum of the reflected light from the wafer is affected, and thus it becomes difficult to grasp the state of the wafer or the processing solution from the obtained optical spectrum. For example, in the etching processing, the information on the state of the wafer surface and the component of the processing solution included in the optical spectrum is shielded by the fluctuation of the optical spectrum due to the undulation of the processing solution, and it may be difficult to read the change of the wafer surface or the processing solution accompanying the progress of the processing from the optical spectrum. In this case, the fluctuation of the light intensity caused by the undulation of the processing solution is noise. On the other hand, it is not noise that fluctuates the light intensity to be measured in relation to the status change of the substrate processing to be detected.

In the present specification, an optical spectrum from which the influence of noise is excluded is referred to as a “corrected optical spectrum”, and a spectrum from which the influence of noise is excluded from each of the current spectrum, the past spectrum, and the reference spectrum is referred to as a “corrected current spectrum”, a “corrected past spectrum”, and a “corrected reference spectrum”.

Referring to FIGS. 1 to 3, in the present embodiment, the substrate processing device 10, the type of the processing solution S, and the configuration of the substrate processing status monitoring device 20 are the same as those of the first embodiment. In the present embodiment, the functions of the operation unit 24 and the like are partially different from those of the first embodiment in order to use the corrected optical spectrum. The differences from the first embodiment will be described below.

In the photometry unit 23 of the present embodiment, it is particularly preferable to shorten the exposure time of the PD array 44 for generating the optical spectrum. The exposure time of the PD array 44 is preferably 2.5 ms or less, and more preferably 1.5 ms or less. This makes it easy to determine the influence of undulation of the processing solution on the optical spectrum.

The operation unit 24 of the present embodiment receives light intensities of a plurality of wavelengths from the photometry unit 23, and calculates a corrected optical spectrum excluding the influence of noise instead of the optical spectrum. The corrected optical spectrum may be calculated from one measurement result of the light intensity received from the photometry unit, or may be calculated from a plurality of measurement results of the light intensity. The corrected optical spectrum generated by the operation unit 24 is recorded in the recording unit 25. Calculating the corrected optical spectrum instead of the optical spectrum does not exclude calculating the corrected optical spectrum and generating the optical spectrum that does not exclude noise as in the first embodiment, and the operation unit 24 may generate both the optical spectrum and the corrected optical spectrum.

The operation unit 24 detects a change in the status of wafer processing by comparing the calculated corrected current spectrum with the corrected reference spectrum or the corrected past spectrum.

The recording unit 25 of the present embodiment records a series of corrected optical spectra and a series of corrected reference spectra calculated during wafer processing.

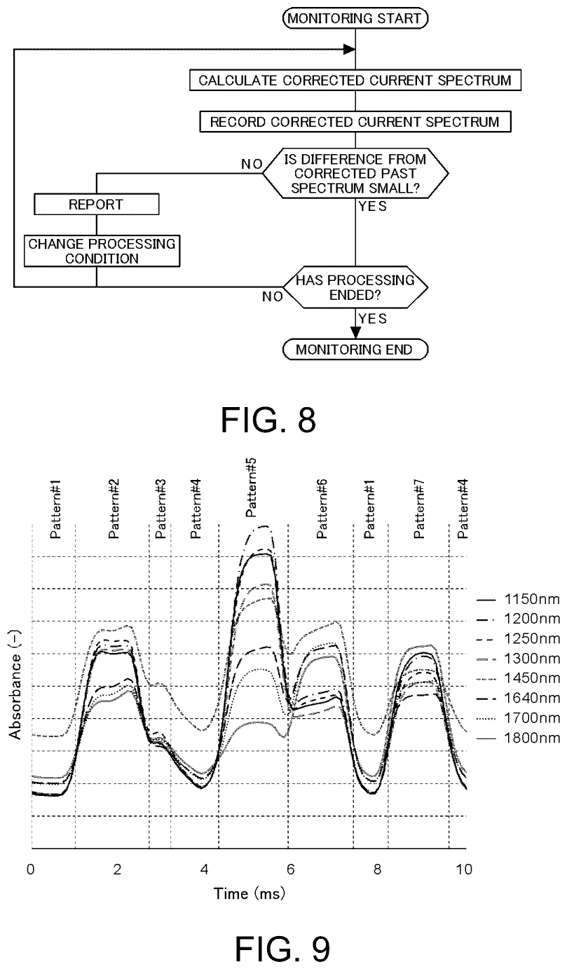

A flow of the method for using the substrate processing status monitoring device 20 according to the present embodiment is illustrated in FIGS. 7 and 8. FIG. 7 illustrates a case where the corrected current spectrum is compared with the corrected reference spectrum, and FIG. 8 illustrates a case where the corrected current spectrum is compared with the corrected past spectrum.

Referring to FIG. 7, a difference from FIG. 5 of the first embodiment is that the operation unit 24 calculates the corrected current spectrum, records the corrected current spectrum in the recording unit 25, compares the corrected current spectrum with the corrected reference spectrum, and updates the corrected reference spectrum as necessary. The comparison between the corrected current spectrum and the corrected reference spectrum can be performed in the same manner as in the comparison between the current spectrum and the reference spectrum in the first embodiment.

Referring to FIG. 8, a difference from FIG. 6 of the first embodiment is that the operation unit 24 calculates the corrected current spectrum, records the corrected current spectrum in the recording unit 25, and compares the corrected current spectrum with the corrected past spectrum. The comparison between the corrected current spectrum and the corrected past spectrum can be performed in the same manner as in the comparison between the current spectrum and the past spectrum in the first embodiment. A specific method for calculating the corrected optical spectrum will be described later.

Here, noise and a method for excluding the noise will be further described. There are two types of noise that can be estimated in advance how the noise affects the optical spectrum and cannot be estimated in advance. The former noise can be removed from the optical spectrum measured at the time of monitoring the substrate processing by a predetermined operation (static data processing). Examples of the former noise include a temperature change of the substrate, a temperature change of the processing solution, absorption by a component of the processing solution, a concentration change of the processing solution, and a change in a liquid film thickness of the processing solution. On the other hand, the latter noise can be removed only by analyzing the optical spectrum measured at the time of substrate processing monitoring (dynamic data processing). A typical example of the latter noise is an undulation of the processing solution.

An example of a method for removing noise by static data processing is as follows. An optical spectrum including light intensities of n wavelengths is measured in advance under the conditions as those of substrate processing to be monitored, and the optical spectrum is represented by an n-dimensional space vector B0. Next, an optical spectrum when factors of noise to be removed (1, 2, . . . , m) are individually changed is measured and represented by n-dimensional space vectors B1, B2, . . . , Bm. A (n-m)-dimensional subspace orthogonal to all of the n-dimensional vectors (B1-B0), (B2-B0), . . . , (Bm-B0) is obtained. When an optical spectrum measured at the time of substrate processing monitoring is represented by an n-dimensional space vector A and projected onto the subspace, an (n-m)-dimensional space vector P is obtained. The obtained vector P is not affected by the noise factor. The number m of factors to be excluded is not particularly limited as long as it is a natural number, and when it is desired to remove only noise due to one factor, it is sufficient to obtain a subspace orthogonal to only (B1-B0) by setting m=1. Details of the method by projecting the optical spectrum onto the subspace are disclosed in Patent Literature 3.

For example, when it is not intended to detect the temperature change of the processing solution, the temperature of the processing solution becomes a factor of noise. When the noise caused by the temperature change of the processing solution is removed, only the temperature of the processing solution is changed and the optical spectra B0 and B1 are measured in advance under the same conditions as in the substrate processing to be monitored, a subspace orthogonal to the vector (B1-B0) is obtained, and the projection of the optical spectrum A measured during the substrate processing onto the subspace is obtained as the vector P, then the vector P does not change depending on the temperature of the processing solution. When the substrate processing monitoring device according to the present embodiment is used with the vector P as a corrected optical spectrum in which the influence of the temperature of the processing solution is excluded, it is not possible to detect an abnormality in the temperature of the processing solution, but it is easy to more clearly monitor a status other than the temperature of the processing solution among the statuses of the processing solution. This method is effective when the temperature of the processing solution can be monitored by a separate means.

In addition, for example, when it is not intended to detect a change in the concentration of the component in the processing solution or the thickness of the processing solution film, a corrected optical spectrum having a large proportion of the interference component in the optical spectrum can be obtained by excluding noise caused by the concentration of the component in the processing solution or cause by the thickness of the processing solution film. This makes it easier to more clearly monitor the status of a portion having a large influence on the interference component, such as the thickness of the thin film on the wafer surface, in the status of the substrate processing. This method is particularly effective when an interference component in the near-infrared region where absorption by the processing solution is large is important.

A typical example of noise requiring dynamic data processing is an undulation of the processing solution. Even when the substrate processing is performed under the same conditions, the undulation of the processing solution is different for each processing. Thus, an operation method for excluding the influence of the waviness from the optical spectrum cannot be determined by a preliminary experiment, and thus the influence of the undulation can be removed only by analyzing the optical spectrum measured at the time of substrate processing monitoring. In addition, the noise due to the undulation becomes a large obstacle in comparing the optical spectrum with the reference spectrum or the like since the status is different for each processing. A method for determining the presence or absence of the influence of the undulation of the processing solution and removing noise caused by the influence will be described in Experiments 2 and 3 described later.

The separation of the absorption component and the interference component of the measured optical spectrum can also be performed by dynamic data processing. For example, the period of interference is obtained by performing discrete Fourier transform (DFT) on the measured optical spectrum with the wave number k on the horizontal axis. A spectrum in which the amplitude of the order component considered as the interference component is reduced is calculated from the result of the DFT, and inverse discrete Fourier transform (IDFT) is performed on the obtained spectrum, whereby an absorption spectrum in which the interference component is removed from the optical spectrum can be obtained.

When the substrate processing monitoring device according to the present embodiment is used, both the comparison between the corrected current spectrum and the corrected reference spectrum (FIG. 7) and the comparison between the corrected current spectrum and the corrected past spectrum (FIG. 8) may be performed. Further, to remove the influence of noise, both static data processing and dynamic data processing may be performed. In addition, both the comparison between the corrected current spectrum and the corrected reference spectrum or the corrected past spectrum and the comparison between the current spectrum and the reference spectrum or the past spectrum described in the first embodiment may be performed.

Next, a third embodiment of the substrate processing status monitoring device of the present invention will be described by taking processing of a semiconductor wafer as an example like the first embodiment. The substrate processing status monitoring device according to the present embodiment performs machine learning.

Referring to FIGS. 1 to 3, in the present embodiment, the substrate processing device 10, the type of the processing solution S, and the configuration of the substrate processing status monitoring device 20 are the same as those of the first embodiment.

A substrate processing status estimation model (hereinafter, simply referred to as an “estimation” model) for estimating an abnormality in the status of the substrate processing is generated in advance by machine learning. As training data, various processing conditions when the same processing as the substrate processing to be monitored is performed, a series of optical spectra during processing, and a processing result are used. The processing conditions are, for example, the rotation speed of the substrate, the type, concentration, temperature, and supply speed of the processing solution. The processing result is, for example, whether the processing has been normally ended, and when an abnormality has occurred, the type of the abnormality that has occurred. The generated learned estimation model is recorded in the recording unit 25.

During the substrate processing, the operation unit 24 inputs various processing conditions and the current spectrum to the estimation model, and obtains the presence or absence of abnormality in the substrate processing and the type of the generated abnormality when the abnormality has occurred as the output of the estimation model. Whether the output of the estimation model is correct is input to the estimation model after the substrate processing ends, and the estimation model is continuously improved.

In the substrate processing status monitoring device according to the present embodiment, by using the substrate processing status estimation model through machine learning, it is easy to know the type of abnormality, for example, liquid shortage of the processing solution, pattern collapse of the wafer surface, and the like on the spot when an abnormality in processing has occurred.

### EXAMPLES

The above-described embodiments will be described in more detail by experimental results. The device used in the experiment is illustrated in FIG. 1, and a tungsten lamp (15 W) was used as the light source 21. Three spectrophotometers illustrated in FIG. 4 were used in parallel for the photometry unit 23, and the light intensity was measured at nine wavelengths in the near-infrared range. Based on the measured value, the operation unit 24 generated an optical spectrum or a corrected optical spectrum represented by light intensities of nine wavelengths.

As Experiment 1, it was checked that a change in the status of the substrate can be detected from the optical spectrum.

In the experiment, a silicon wafer having a diameter of 200 mm and different patterned regions arranged in the circumferential direction was rotated at 1000 rpm, and a position of 31.5 mm from the center of the wafer was irradiated with light while pure water was supplied at 0.5 L/min to the center of the wafer, and an optical spectrum was generated from reflected light. The sampling exposure time was 100 μs.

FIG. 9 illustrates the change in light intensity at each wavelength measured during 10 ms. The position on the wafer where reflected light is emitted moves in the circumferential direction along with the rotation of the wafer, and shifts to a region of another adjacent pattern through several times of sampling. It can be seen from FIG. 9 that the optical spectrum of the received reflected light is clearly different depending on the difference in the pattern formed on the wafer surface. From this result, it has been confirmed that it is possible to monitor the state of the surface of the wafer during the processing of the wafer performed while supplying a processing solution, for example, it is possible to detect the collapse of the pattern of the wafer during the processing, using the substrate processing status monitoring device of the first embodiment.

As Experiment 2, it was checked that the influence of undulation of the processing solution can be determined.

In the experiment, an unpatterned silicon wafer having a diameter of 200 mm was rotated at 500 rpm, and a position of 50 mm from the center of the wafer was irradiated with light while pure water was supplied at 1.0 L/min to the center of the wafer, and an optical spectrum was generated from reflected light. The sampling exposure time was 1 ms.

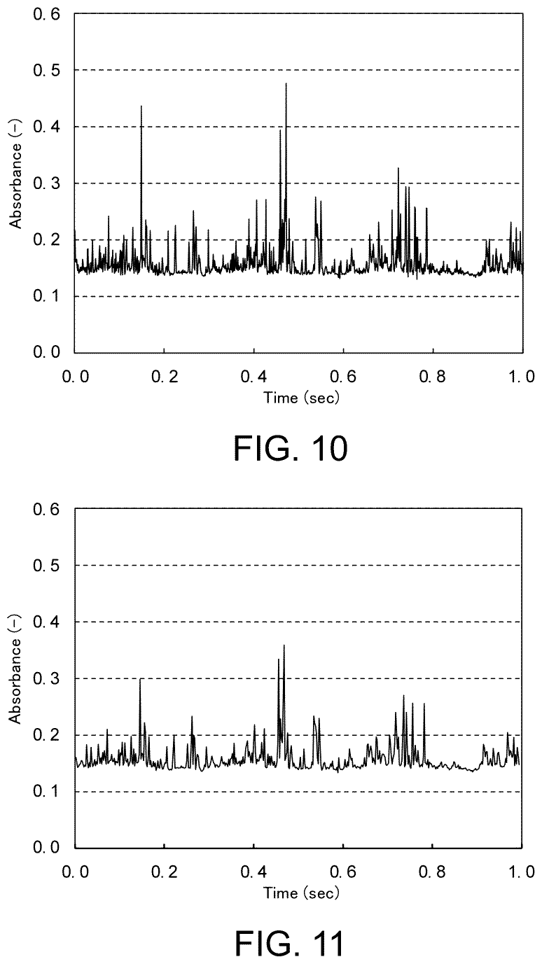

FIG. 10 illustrates the absorbance calculated from received light intensity at a wavelength of 1300 nm. The absorbance A was calculated by the following formula with the measured received light intensity as I and the received light intensity when pure water was not supplied as I₀.

$$A = - log ( I / {I}_{0} )$$

In FIG. 10, the received light intensity is plotted for 1 second, that is, 1000 times of measurements. In FIG. 10, the absorbance varied greatly, and a remarkably large value was sometimes observed. From this result, it was considered that the fluctuation in the light intensity due to the waviness of the processing solution is not merely caused by a change in the magnitude of the thickness of the processing solution film, but is caused by the light irradiated to the processing solution being scattered and the amount of light returning to the light receiving unit being reduced. Then, it was confirmed that the fluctuation of the light intensity due to the undulation of the processing solution can be clearly determined when the exposure time is 1 ms.

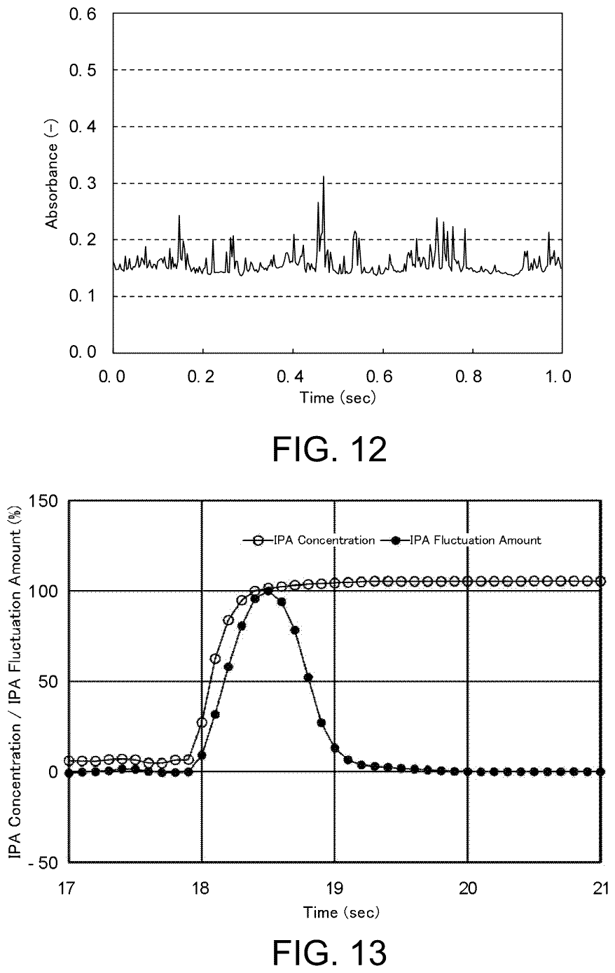

FIGS. 11 and 12 illustrate the absorbance calculated after light reception intensities in the experiment of FIG. 10 are integrated two times or three times, respectively. FIGS. 11 and 12 correspond to results in a case where the exposure time is 2 ms and 3 ms, respectively. Comparing FIGS. 10 to 12, it can be seen that the shorter the exposure time, the easier it is to determine the influence of the undulation of the processing solution on the light intensity. From this result, it was found that the exposure time of the photometry unit is preferably 2.5 ms or less, and more preferably 1.5 ms or less.

From the experiments in which the rotation speed of the silicon wafer was changed in the range of 100 to 1000 rpm and the supply speed of pure water was changed in the range of 0.1 to 1.0 L/min, the same results were obtained as the preferable range of the exposure time.

As Experiment 3, the effect of using the corrected optical spectrum obtained by excluding the influence of noise due to the undulation of the processing solution from the optical spectrum was checked by measuring the component concentration in the processing solution.

In the experiment, an unpatterned silicon wafer having a diameter of 200 mm was rotated at 1000 rpm, pure water was supplied to the center of the wafer at 50 mL/min for 18 seconds, and then pure water supply was stopped, and IPA was supplied at 50 mL/min for about 20 seconds. A position of 50 mm from the center of the wafer was irradiated with light, and the light intensities of nine wavelengths were measured from reflected light. The exposure time was set to 1 ms, the absorbance was obtained by excluding the influence of the processing solution from the light intensity measured 100 times for 0.1 seconds, and multivariate analysis was performed using a group of absorbance data measured in advance while changing the liquid film thickness and the IPA-water mixing ratio to obtain the IPA concentration and the liquid film thickness in the processing solution on the wafer.

The influence of the undulation of the processing solution was excluded by the following method. For each wavelength, the absorbance was calculated from each of 100 light intensities measured for 0.1 seconds, and 10 absorbance data with small values were unconditionally regarded as abnormal values and excluded. Then, the minimum value among the remaining 90 values was regarded as a normal value of the absorbance and used as a reference value. The reference value is a value that is considered to be a normal value extremely reliably, and the 10 pieces of data unconditionally excluded may include a normal value. Next, with the reference value +0.2 as a threshold value, data exceeding the threshold value among the 90 pieces of absorbance data was determined as abnormal values, and data equal to or less than the threshold value was left as normal values. The threshold value may be determined in advance to a certain value, for example, the expected maximum absorbance, or may be determined according to a reference value and a predetermined calculation formula as in this experiment. From the absorbance data left as normal values, the IPA concentration in the processing solution on the wafer was determined by multivariate analysis.

FIG. 13 illustrates the measurement results of the abundance of IPA on the wafer before and after the processing solution was switched from pure water to IPA. The horizontal axis represents the lapse of time, and the vertical axis represents the concentration of IPA. Open circles indicate the IPA concentration of every 0.1 seconds calculated based on the absorbance value determined not to be an abnormal value. The black circle is an index of the temporal change of the IPA concentration, and is an absolute value of the difference between the maximum value and the minimum value of the concentration of the last five times. The IPA concentration exceeded 100% because of a quantitative error, but the change in the calculated IPA concentration is smooth, and the IPA fluctuation amount after the processing solution is replaced with IPA is also stable.

The results of FIG. 13 show that the component amount in the processing solution can be accurately quantified by excluding the influence of the undulation of the processing solution, and it was found from the results that the progress of the entire substrate processing can be more clearly monitored by excluding the influence of noise due to the processing solution.

In order to monitor the status of the substrate processing in real time, it is necessary to obtain the current spectrum or the corrected current spectrum at a sampling interval that is short to some extent, and the sampling interval is said to be preferably 0.5 seconds or less, more preferably 0.25 seconds or less, and particularly preferably 0.1 seconds or less. Thus, even when an optical spectrum is generated from the result of one measurement of the light intensity, the exposure time is preferably 0.5 seconds or less, more preferably 0.25 seconds or less, and particularly preferably 0.1 seconds or less. In addition, when the corrected optical spectrum excluding the influence of the processing solution is calculated by the method of Experiment 3, it is necessary to perform light intensity measurement a plurality of times within the above-described time period. According to the result of statistically processing the variation in the light intensity in Experiment 2, for example, assuming that the tolerance is 0.05, it is necessary to perform the light intensity measurement about 30 to 50 times in the 95% confidence interval and about 60 to 80 times in the 99% confidence interval within the above-described time period.

The present invention is not limited to the above embodiments or examples, and various modifications can be made within the scope of the technical idea.

For example, the substrate processing status monitoring device and the substrate processing status monitoring method are not limited to those for the processing solution on a silicon wafer, and the substrate may be a compound semiconductor such as silicon carbide or gallium arsenide, a crystal wafer such as sapphire, or a glass substrate.

In addition, for example, in the above-described embodiments, the substrate processing status is monitored by emitting light vertically from the probe 22 that serves as both a light projecting unit and a light receiving unit toward the upper surface of the wafer W, and receiving the light that has passed through the processing solution and reflected from the wafer W by the probe 22. However, the light projecting unit and the light receiving unit may be separated, and the light projecting unit may obliquely emit light to the upper surface of the wafer W, and the light that has passed through the processing solution and reflected from the wafer W may be received by the light receiving unit. Further, the substrate processing status may be monitored using light transmitted through the wafer W. Specifically, it is possible to detect a change in the status of the substrate processing by irradiating a wafer with light from a light projecting unit disposed above or under the wafer, receiving light passing through the wafer and the processing solution with a light receiving unit facing the light projecting unit across the wafer, and generating an optical spectrum or the like of the received transmitted light.

### REFERENCE SIGNS LIST

10 substrate processing device
11 rotary table
12 nozzle
13 pipe
20 substrate processing status monitoring device
21 light source
22 probe (light projecting unit, light receiving unit)
23 photometry unit
24 operation unit
25 recording unit
26 control unit
28 optical fiber
31, 33 lens
32 mirror
42 slit
43 linear variable filter (LVF)
44 photodiode array (PD array)
45 photodiode element (PD element)
50 spectrophotometer
51 lens
52 partition wall
53 opening
54 bandpass filter (BPF)
55 light detection element
56 housing
B light beam
F processing solution film
S processing solution
W wafer (substrate)
X optical axis of spectrophotometer

1. A substrate processing status monitoring device for monitoring a status of substrate processing performed by supplying a processing solution onto a substrate that is rotating, the substrate processing status monitoring device comprising:
a light projecting unit that irradiates the substrate with light;
a light receiving unit that receives light that has passed through the processing solution;
a photometry unit that simultaneously disperses light received by the light receiving unit into a plurality of wavelengths and simultaneously measures light intensities of the plurality of wavelengths; and
an operation unit that detects a change in the status of the substrate processing by generating an optical spectrum from the light intensities of the plurality of wavelengths measured by the photometry unit and comparing the optical spectrum with a reference spectrum or the optical spectrum of past previously generated during the substrate processing.

2. The substrate processing status monitoring device according to claim 1,
wherein the operation unit:
detects the change in the status of the substrate processing by comparing the optical spectrum with the reference spectrum; and
updates the reference spectrum using the optical spectrum.

3. The substrate processing status monitoring device according to claim 1, wherein the operation unit detects the change in the status of the substrate processing by calculating a corrected optical spectrum obtained by excluding an influence of noise from the optical spectrum instead of the optical spectrum from the light intensities of the plurality of wavelengths measured by the photometry unit and comparing the corrected optical spectrum with a corrected reference spectrum obtained by excluding the influence of noise from the reference spectrum or the corrected optical spectrum of past previously calculated during the substrate processing.

4. The substrate processing status monitoring device according to claim 3, wherein the operation unit calculates the corrected optical spectrum and the corrected reference spectrum by excluding the influence of noise from the optical spectrum and the reference spectrum, respectively, through dynamic data processing.

5. The substrate processing status monitoring device according to claim 4, wherein the noise is noise caused by an undulation of the processing solution.

6. The substrate processing status monitoring device according to claim 3, wherein the operation unit:
detects the change in the status of the substrate processing by comparing the corrected optical spectrum with the corrected reference spectrum; and
updates the corrected reference spectrum using the corrected optical spectrum.

7. The substrate processing status monitoring device according to claim 1, further comprising a control unit that changes a condition of the substrate processing based on the change in the status of the substrate processing that has been detected.

8. The substrate processing status monitoring device according to claim 1, wherein the photometry unit measures the light intensities of the plurality of wavelengths using a time that is a natural number multiple of a rotation period of the substrate as an exposure time.

9. The substrate processing status monitoring device according to claim 1, wherein the photometry unit measures the light intensities of the plurality of wavelengths in an exposure time of 2.5 milliseconds or less.

10. The substrate processing status monitoring device according to claim 1, wherein the photometry unit disperses the light received by the light receiving unit into 32 or more of wavelengths.

11. The substrate processing status monitoring device according to claim 1,
wherein the photometry unit includes a linear variable filter and disperses the light received by the light receiving unit with the linear variable filter.

12. A substrate processing status monitoring device for monitoring a status of substrate processing performed by supplying a processing solution onto a substrate that is rotating, the substrate processing status monitoring device comprising:
a light projecting unit that irradiates the substrate with light;
a light receiving unit that receives light that has passed through the processing solution;
a photometry unit that simultaneously disperses light received by the light receiving unit into a plurality of wavelengths and simultaneously measures light intensities of the plurality of wavelengths; and
an operation unit that estimates an abnormality of the substrate processing by calculating an optical spectrum or a corrected optical spectrum obtained by excluding an influence of noise from the light intensities of the plurality of wavelengths measured by the photometry unit and inputting the optical spectrum or the corrected optical spectrum to a substrate processing status estimation model learned through machine learning for estimating an abnormality of the status of the substrate processing.

13. A substrate processing status monitoring method for monitoring a status of substrate processing performed by supplying a processing solution onto a substrate that is rotating, the substrate processing status monitoring method comprising:
a light projecting step of irradiating the substrate with light;
a light receiving step of receiving light that has passed through the processing solution and is reflected from a surface of the substrate;
a photometry step of simultaneously dispersing light received in the light receiving step into a plurality of wavelengths and simultaneously measuring light intensities of the plurality of wavelengths;
an optical spectrum generation step of generating an optical spectrum from the light intensities of the plurality of wavelengths measured in the photometry step; and
a detection step of detecting a change in the status of the substrate processing by comparing the optical spectrum with a reference spectrum or the optical spectrum of past previously generated during the substrate processing.

14. The substrate processing status monitoring method for monitoring a status of substrate processing according to claim 13, comprising, instead of the optical spectrum generation step, a corrected optical spectrum calculation step of calculating a corrected optical spectrum obtained by excluding an influence of noise from the light intensities of the plurality of wavelengths measured in the photometry step, wherein the detection step is a step of detecting the change in the status of the substrate processing by comparing the corrected optical spectrum with a corrected reference spectrum from which the influence of noise is excluded or the corrected optical spectrum of past previously calculated during the substrate processing.
